(19) United States
(12) Patent Application Publication
(10) Pub. No.: US 2022/0308285 A1
(43) Pub. Date: Sep. 29, 2022

(54) SILICON PHOTONICS-BASED PHOTODETECTOR

(71) Applicant: ELECTRONICS AND TELECOMMUNICATIONS RESEARCH INSTITUTE, Daejeon (KR)

(72) Inventors: Dongjun SEO, Daejeon (KR); Heuk PARK, Daejeon (KR); Sanghwa YOO, Daejeon (KR); Joon Ki LEE, Sejong-si (KR)

(21) Appl. No.: 17/540,439

(22) Filed: Dec. 2, 2021

(30) Foreign Application Priority Data
Mar. 24, 2021 (KR) 10-2021-0037772

(51) Int. Cl. G02B 6/12; H01L 31/0232; H01L 31/028; H01L 31/105

(52) U.S. Cl. CPC G02B 6/12004; H01L 31/02327; H01L 31/028; H01L 31/105

(57) ABSTRACT

A silicon photonics-based photodetector (PD) includes a silicon layer on which doped layers of different types are formed on a surface based on a first spacing based on a center line of an optical waveguide through which an optical signal moves, a germanium layer being stacked on an upper part of the silicon layer and formed with doped layers of different types on a surface based on a second spacing based on the center line of the optical waveguide, and a metal electrode configured to generate an electric field by being in contact with the doped layers of the silicon layer and the germanium layer.

### CROSS-REFERENCE TO RELATED APPLICATION

This application claims the benefit of Korean Patent Application No. 10-2021-0037772 filed on Mar. 24, 2021, in the Korean Intellectual Property Office, the entire disclosure of which is incorporated herein by reference for all purposes.

### BACKGROUND

### 1. Field of the Invention

One or more example embodiments relate to a silicon photonics-based photodetector (PD), and more particularly, an apparatus for generating a strong electric field in a wide region by arranging, in a vertical direction, a horizontal positive-intrinsic-negative (PIN) structure or a PN-negative-intrinsic-positive (NIP) (or NP-PIN) structure having opposite doped types in the PD.

### 2. Description of Related Art

Developments in various technologies using big data are continuously increasing traffic in data centers. To process the traffic, there is a need for a technology that may process a high-speed signal. Silicon photonics technology may be a possible solution for interconnection in data centers because it is highly integrable, uses less power, and is compatible with a complementary metal-oxide-semiconductor (CMOS) process.

Among core devices for implementing silicon photonics-based interconnection technology, a photodetector (PD), which receives an optical signal, may be a core functional device that needs high performance to enable transmission and reception of high-speed signals. Among various PD structures, a positive-intrinsic-negative (PIN) diode structure may support high bandwidth due to its rapid response time and be more desirable for high-speed transmission and reception products.

It may be desirable to provide a PD of a PIN diode in a form connected to an optical waveguide for a system on a chip. When the light injected through the optical waveguide is absorbed in an intrinsic region and converted to an electron-hole pair, the light may be moved by an electric field to a P-type or N-type layer. The PD of the PIN diode may be classified as a vertical structure and a horizontal structure based on a direction in which a PIN layer is formed.

A vertical PIN diode PD may have a P-type doped layer disposed on an upper part of a silicon layer and an N-type doped layer disposed on an upper part of a germanium layer. An intrinsic region may be formed in germanium and be at a boundary interface of the germanium layer and the silicon layer or in a region between a silicon-germanium buffer layer and the N-type doped layer. An optical signal may travel along an optical waveguide, pass through the silicon layer under the germanium layer, and be absorbed by the germanium layer that is formed on the silicon layer.

Using the vertical PIN diode PD may simplify a process because diodes are configured to be in the same direction in which silicon and germanium are stacked. However, since the germanium may not be formed in a cuboid, some carriers generated by photoelectric conversion may need to move in a weak fringe electric field («5 kilovolts per centimeter (kV/cm)), which may reduce a maximum bandwidth.

In addition, the thickness of the germanium may simultaneously determine an efficiency of an optical signal being coupled in the silicon layer, an electric capacitance of a PIN diode, and a traveling distance of the carrier. An overall performance of the PD may be determined based on an accuracy of a germanium growth process.

While a horizontal PIN diode PD may be formed in an upper part of the germanium layer or the silicon layer, these days the horizontal PIN diode PDs are being formed in the silicon layer such that a metal is not included in the upper part of germanium to improve a response time.

In the horizontal PIN diode PD, an intrinsic region is generally positioned in the silicon layer, and the optical signal coupling method may be the same as that of the vertical PIN diode PD. Thus, a carrier generated by photoelectric conversion may move based on a fringe electric field formed in a germanium region by a PIN structure formed in the silicon layer.

When the germanium layer is sufficiently thin, as there is no need for a metal to be formed in the germanium layer, the horizontal PIN diode PD may form a strong electric field for an entire intrinsic region between P-type and N-type doped layers, thereby preventing a PD response time from decreasing.

However, when the horizontal PIN diode structure is formed on the silicon layer, a fringe electric field being formed inside germanium may be used, and an intensity of an electric field formed on an upper part of the germanium layer may become weaker as the germanium becomes thicker. That is, the thickness of the germanium being thin may lead to high intensity for generating a carrier at a part where an optical signal starts being absorbed, generate an electric field screening effect, and thus reduce a traveling speed of the carrier.

### SUMMARY

Example embodiments provide an apparatus and method for increasing a travelling speed of a carrier by arranging, in a vertical direction, a horizontal positive-intrinsic-negative (PIN) structure or a PN-negative-intrinsic-positive (NIP) (or NP-PIN) structure having opposite doped types and generating a strong electric field in a wide region in a photodetector (PD).

Example embodiments provide an apparatus and method for alleviating performance degradation that may occur due to a carrier concentration by controlling a width of an intrinsic region of the PIN structure formed in a silicon layer to control a ratio of a carrier moving to an upper part of a germanium layer or the silicon layer.

According to an aspect, there is provided a silicon photonics-based photodetector (PD), including a silicon layer on which doped layers of different types are formed on a surface based on a first spacing based on a center line of an optical waveguide through which an optical signal moves, a germanium layer being stacked on an upper part of the silicon layer and formed with doped layers of different types on a surface based on a second spacing based on the center line of the optical waveguide, and a metal electrode configured to generate an electric field by being in contact with the doped layers of the silicon layer and the germanium layer.

The doped layers formed on the silicon layer and the doped layers formed on the germanium layer may be geometrically asymmetrical based on a horizontal plane of the germanium layer and have opposite doped types.

The doped layers formed on the silicon layer and the doped layers formed on the germanium layer may be geometrically symmetrical based on a vertical plane of the germanium layer and have opposite doped types.

A distribution of a fringe electric field formed in the germanium layer may be determined by the first spacing between the doped layers formed on the silicon layer and the second spacing between the doped layers formed on the germanium layer.

For the distribution of the fringe electric field formed in the germanium layer, a horizontal component of the fringe electric field and a vertical component of the fringe electric field may be entirely offset when the first spacing between the doped layers formed on the silicon layer and the second spacing between the doped layers formed on the germanium layer are the same.

For the distribution of the fringe electric field formed in the germanium layer, a horizontal component of the fringe electric field may be offset, and a vertical component of the fringe electric field may be reinforced when the first spacing between the doped layers formed on the silicon layer and the second spacing between the doped layers formed on the germanium layer are different.

A position where an electric field is reduced by an offset fringe electric field may be determined by a difference in the first spacing between the doped layers formed on the silicon layer and the second spacing between the doped layers formed on the germanium layer.

Of the doped layers of different types formed on the silicon layer, the first spacing may be controlled to reduce an amount of loss occurring when a carrier is generated.

According to another aspect, there is provided a silicon photonics-based PD, including a silicon layer on which doped layers of different types are formed on a surface based on a first spacing based on a center line of an optical waveguide through which an optical signal moves, and a germanium layer on which doped layers being geometrically asymmetrical based on a horizontal plane, geometrically symmetrical based on a vertical plane, and having opposite doped types compared to the doped layers formed on the silicon layer are formed on a surface based on a second spacing.

A distribution of a fringe electric field formed in the germanium layer may be determined by the first spacing between the doped layers formed on the silicon layer and the second spacing between the doped layers formed on the germanium layer.

For the distribution of the fringe electric field formed in the germanium layer, a horizontal component of the fringe electric field and a vertical component of the fringe electric field may be entirely offset when the first spacing between the doped layers formed on the silicon layer and the second spacing between the doped layers formed on the germanium layer are the same.

For the distribution of the fringe electric field formed in the germanium layer, a horizontal component of the fringe electric field may be offset, and a vertical component of the fringe electric field may be reinforced when the first spacing between the doped layers formed on the silicon layer and the second spacing between the doped layers formed on the germanium layer are different.

A position where an electric field is reduced by an offset fringe electric field may be determined by a difference in the first spacing between the doped layers formed on the silicon layer and the second spacing between the doped layers formed on the germanium layer.

Of the doped layers of different types formed on the silicon layer, the first spacing may be controlled to reduce an amount of loss occurring when a carrier is generated.

According to another aspect, there is provided a silicon photonics-based PD, including a buried oxide (BOX) layer of a silicon-on-insulator (SOI) wafer, a silicon layer being stacked on an upper part of the BOX layer and formed with doped layers of different types on a surface based on a first spacing based on a center line of an optical waveguide through which an optical signal moves, a germanium layer being stacked on an upper part of the silicon layer and formed with doped layers of different types on a surface based on a second spacing based on a center line of the optical waveguide, and a metal electrode configured to generate an electric field by being in contact with the doped layers of the silicon layer and the germanium layer.

The doped layers formed on the silicon layer and the doped layers formed on the germanium layer may be geometrically asymmetrical based on a horizontal plane of the germanium layer and have opposite doped types.

The doped layers formed on the silicon layer and the doped layers formed on the germanium layer may be geometrically symmetrical based on a vertical plane of the germanium layer and have opposite doped types.

A distribution of a fringe electric field formed in the germanium layer may be determined by the first spacing between the doped layers formed on the silicon layer and the second spacing between the doped layers formed on the germanium layer.

Additional aspects of example embodiments will be set forth in part in the description which follows and, in part, will be apparent from the description, or may be learned by practice of the disclosure.

According to example embodiments, a traveling speed of a carrier may be increased by arranging, in a vertical direction, a horizontal PIN structure or a PN-NIP (or NP-PIN) structure having opposite doped types and generating a strong electric field in a wide region in a PD.

According to example embodiments, a performance degradation that may occur due to a carrier concentration may be alleviated by controlling a width of an intrinsic region of a horizontal PIN structure formed in a silicon layer to control a ratio of a carrier moving to an upper part of a germanium layer or a silicon layer.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIGS. 1A through 1C are diagrams illustrating examples of a structure of a silicon photonics-based photodetector (PD) according to example embodiments; and

FIGS. 2 through 4 are diagrams illustrating examples of distributions of an intensity of an electric field formed in a region 70a illustrated in FIGS. 1B and 1C for a vertical PIN structure, a horizontal PIN structure, and a proposed structure described herein according to example embodiments.

### DETAILED DESCRIPTION

Hereinafter, example embodiments will be described in detail with reference to the accompanying drawings.

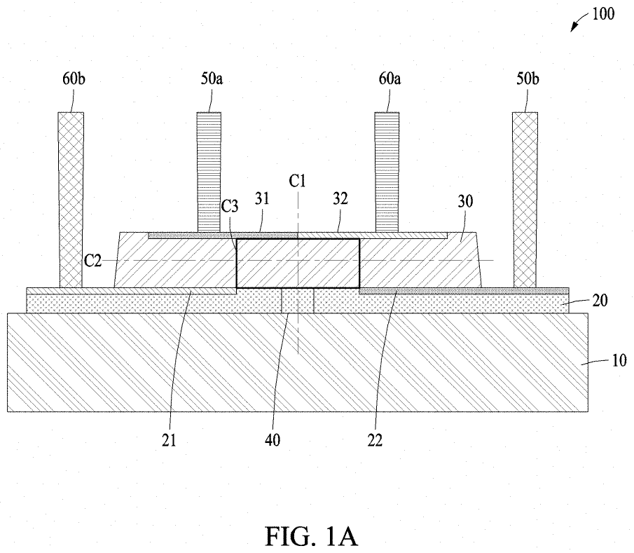

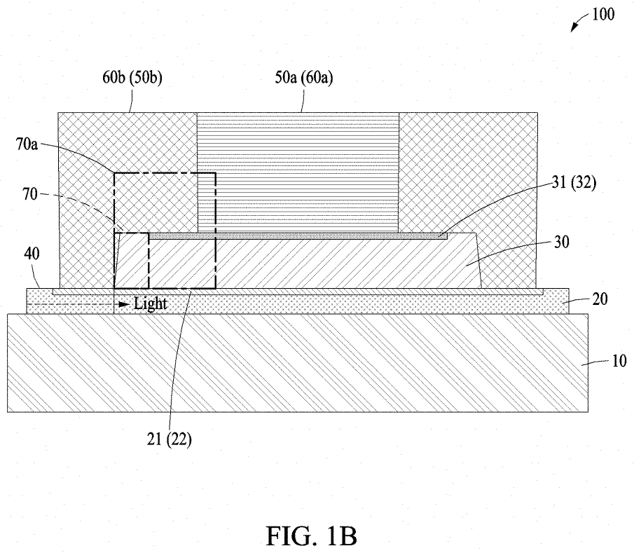

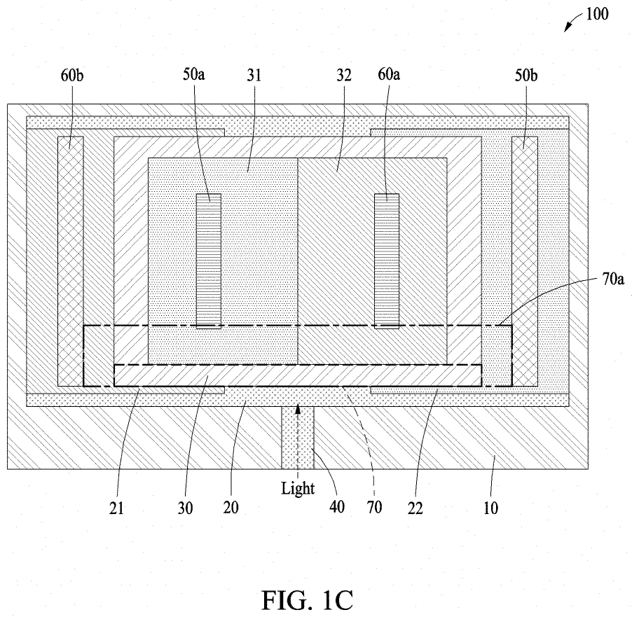

FIGS. 1A through 1C are diagrams illustrating examples of a structure of a silicon photonics-based photodetector (PD) according to example embodiments.

FIG. 1A illustrates a front view of a silicon photonics-based PD 100, FIG. 1B illustrates a side view of the silicon photonics-based PD 100, and FIG. 1C illustrates a plane view of the silicon photonics-based PD 100.

The silicon photonics-based PD 100 may distribute a strong electric field of 5 kilovolts per centimeter (kV/cm) or more in a wide region in the silicon photonics-based PD 100 by appropriately arranging a doped region to increase a traveling speed of an electron, and thus provide a method of improving bandwidth features by reducing a traveling time.

The silicon photonics-based PD 100 may include a buried oxide (BOX) layer 10 on a silicon-on-insulator (SOI) wafer, a silicon layer 20 and a germanium layer 30 sequentially formed on an upper part of the BOX layer 10, N-type doped layers 21 and 32 and P-type doped layers 22 and 31 for a diode formation, and metal electrodes 50a, 50b, 60a, and 60b for an electrical connection.

Here, an optical signal may travel along a silicon optical waveguide 40 connected to the silicon layer 20 of the silicon photonics-based PD 100. The silicon photonics-based PD 100 may be implemented by forming the germanium layer 30 through epitaxial growth and include, for example, the BOX layer 10 having a thickness of 2 to 3 micrometers (μm), the silicon layer 20 having a thickness of 200 to 400 nanometers (nm), and the silicon optical waveguide 40 sequentially stacked on a silicon substrate having a thickness of 725 μm or less.

A reverse voltage of the silicon photonics-based PD 100 may be implemented by applying a higher voltage on metal electrodes 60a and 60b corresponding to a cathode than on metal electrodes 50a and 50b corresponding to an anode.

Referring to FIG. 1A, doped layers 21, 22, 31, and 32 of the silicon photonics-based PD 100 may be geometrically symmetrical based on a vertical plane C1 of the germanium layer 30 and have opposite doped types. In addition, the doped layers 21, 22, 31, and 32 of the silicon photonics-based PD 100 may be geometrically asymmetrical based on a horizontal plane C2 of the germanium layer 30 and have opposite doped types. When doped layers 21 and 32 are of an N-type, doped layers 22 and 31 may be of a P-type, and when the doped layers 21 and 32 are of a P-type, the doped layers 22 and 31 may be of an N-type. Thus, four types of electric field may be generated in the silicon photonics-based PD 100 in which the doped layers 21, 22, 31, and 32 are present.

(i) First Type of Electric Field

Doped layers 21 and 31 and doped layers 22 and 32 may form a positive-intrinsic-negative (PIN) diode in the same direction (vertical direction) as a direction in which the silicon layer 20 and the germanium layer 30 are stacked. A first type of electric field having a linear flux form of a uniform size in a stacking direction and an opposite stacking direction may be formed in doped regions facing each other in parallel among the doped layers 21 and 31 and the doped layers 22 and 32. That is, the first type of electric field may be formed outside of a region C3 in the germanium layer 30.

(ii) Second Type of Electric Field

Since doped layers 21 and 22 and doped layers 31 and 32 are geometrically asymmetrical based on a horizontal plane C2 of the germanium layer 30, a curved flux form may be obtained from a long-to-short direction or from a short-to-long direction, and thus a second type of electric field may be formed. That is, the second type of electric field may form a fringe electric field that changes a position of an electric field based on a distance of the region C3 in the germanium layer 30.

(iii) Third Type of Electric Field

The doped layers 21 and 22 may include a PIN diode in the same direction (horizontal direction) as a horizontal plane C2 of the germanium layer 30 and form a uniform electric field in an intrinsic silicon region between the doped layers 21 and 22, and the fringe electric field may be formed at the region C3 in the germanium layer 30.

(iv) Fourth Type of Electric Field

The doped layers 31 and 32 may form a PN or a PIN diode based on whether spacing is present or absent and form a fringe electric field that is symmetrical based on a formation direction of C2 compared to the third type of electric field in the region C3.

Since a distribution of the fringe electric field is determined by spacing between doped layers forming a field, the third type of electric field and the fourth type of electric field may completely offset each other when spacing between the doped layers 21 and 22 and between the doped layers 31 and 32 are the same.

Conversely, when the spacing between the doped layers 21 and 22 and between the doped layers 31 and 32 are different, horizontal components among vector components of the fringe electric field for the third type of electric field and the fourth type of electric field may be in opposite directions and offset each other, and vertical components may be in the same direction and be reinforced.

Due to a field offset, a part of an electric field in a structure of the silicon photonics-based PD 100 may be weakened, and a position of the part where the electric field is weakened may be determined by a spacing difference between the doped layers 21 and 22 and between the doped layers 31 and 32.

In more detail, when the spacing between the doped layers 21 and 22 and between the doped layers 31 and 32 are the same, the part where the electric field is weakened may be positioned at a center of the germanium layer 30, and as the spacing between the doped layers 31 and 32 and the spacing between the doped layers 21 and 22 becomes greater, the part where the electric field is weakened may move towards the silicon layer 20, and thus the traveling speed of the carrier may be less affected.

In addition, since the doped layers 21 and 22 formed on the silicon layer 20 are positioned to be in contact with the silicon optical waveguide 40, a loss may be reduced by controlling the spacing between the doped layers 21 and 22 when a carrier is being generated.

Silicon does not usually absorb an O- or C-band wavelength used for communication. However, when an impurity is added for doping, light may be absorbed, and an amount of a carrier being generated in the germanium layer 30 may be reduced.

A silicon slab connected to the optical waveguide 40 may be in a form of a silicon layer that is wider than the optical waveguide 40, and the light may be spread widely after being coupled from the optical waveguide 40 to determine how much light is absorbed in a wide range.

When the spacing between the doped layers 21 and 22 is narrower than a range in which light is absorbed, the light may be absorbed in the silicon as described above, and a loss may occur in an amount of a carrier being generated. Thus, a loss may be minimized by controlling the spacing between the doped layers 21 and 22 to be in a similar or wide range.

As illustrated in FIGS. 1B and 1C, a region 70 in which no doping is performed may be formed at an edge of the germanium layer 30 when doped layers are formed on the germanium layer 30 because the edge of the germanium layer 30 is not formed completely perpendicular to a bottom surface in a growth process even if the germanium layer 30 is grown in a cube shape. In addition, a formation error may need to be considered when a doped layer is being formed.

Thus, when the doped layers are formed in a vertical PIN structure that is generally used, a relatively weak fringe electric field («5 kV/cm) may be formed in the region 70. When a horizontal PIN structure is formed on the silicon layer 20, an electric field of 5 kV/cm or more may be formed in a region close to the silicon layer 20. However, as the germanium layer 30 becomes thicker, an intensity of a fringe electric field formed in the upper part of the germanium layer 30 may be weaker. Since an electric field is mostly not formed in a region outside of the intrinsic region of the silicon layer 20 having a horizontal PIN structure, a width of the germanium layer 30 may be limited to a size of the intrinsic region. Thus, an optical signal that may be received without a feature degradation may be limited, and a maximum power of the optical signal may be limited.

To resolve such an issue, the silicon photonics-based PD 100 may arrange, in a vertical direction, a horizontal PIN structure or a PN-NIP (NP-PIN) structure having opposite doped types and generate a strong electric field in a wide region. A width of an intrinsic region of the horizontal PIN structure formed in the silicon layer 20 may be controlled to control a ratio of a carrier moving to the upper part of the germanium layer 30 or the silicon layer 20. Thus, a traveling distance of the carrier may be optimized. When the carrier moves in a single direction, such as a vertical direction or a horizontal direction, a width and height of the germanium layer may be limited to optimize the traveling distance of the carrier. For the proposed structure described herein, the carrier may travel in both horizontal and vertical directions, which relatively alleviates a size limit on the germanium, and thus reduces performance degradation that may occur due to a carrier concentration.

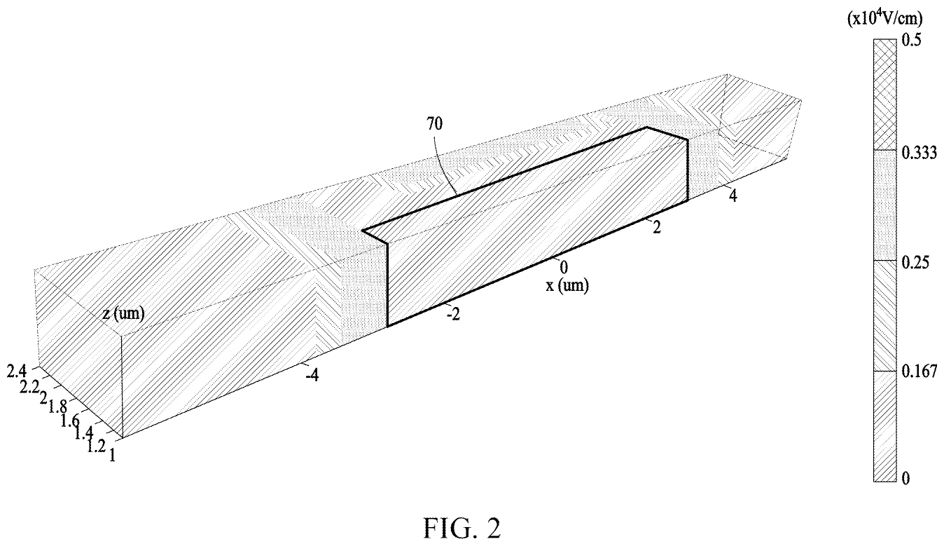

FIGS. 2 through 4 are diagrams illustrating examples of a distribution of an electric field formed in the region 70a illustrated in FIGS. 1B and 1C for a vertical PIN structure, a horizontal PIN structure, and a proposed structure described herein according to example embodiments.

In FIGS. 2 through 4, x denotes a width direction, y denotes a longitudinal direction, and z denotes a height direction of the region 70a. An intensity of an electric field is represented in a color bar form, and a maximum value of a color bar may be 5 kV/cm.

FIG. 2 is a diagram illustrating an example of an electric field intensity distribution in the region 70a for a vertical PIN structure in which different types of doped layers are formed on an upper part of the germanium layer 30 and the silicon layer 20. Referring to FIG. 2, a magnetic field in the entire region 70 may be extremely weak (less than 1 kV/cm) in the vertical PIN structure such that a carrier may not reach a saturation velocity.

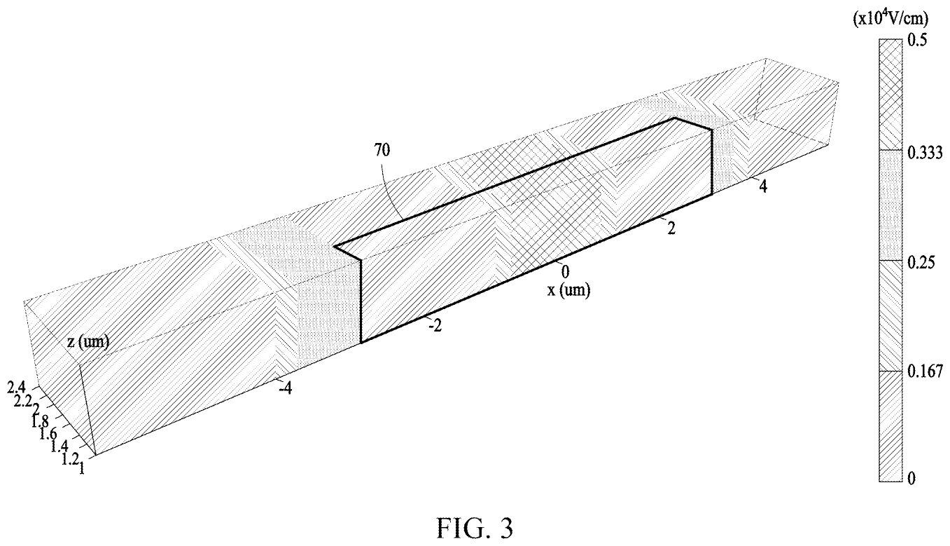

FIG. 3 is a diagram illustrating an example of an electric field intensity distribution in the region 70a for a horizontal PIN structure in which different types of doped layers are formed on the silicon layer 20. Referring to FIG. 3, a strong magnetic field may be formed in a region as wide as the intrinsic region in the horizontal PIN structure, but electrons outside of the intrinsic region may be accelerated by a very weak electric field and may not reach a saturation velocity.

When the intrinsic region of the silicon layer 20 is widened to expand the strong magnetic field in the horizontal PIN structure, the number of carriers affected by a strong electric field may increase, but a required voltage to maintain the same intensity for the electric field may also be greater, which increases a traveling time of a carrier by increasing a traveling distance of the carrier, and thus a performance degradation of the silicon photonics-based PD 100 may occur.

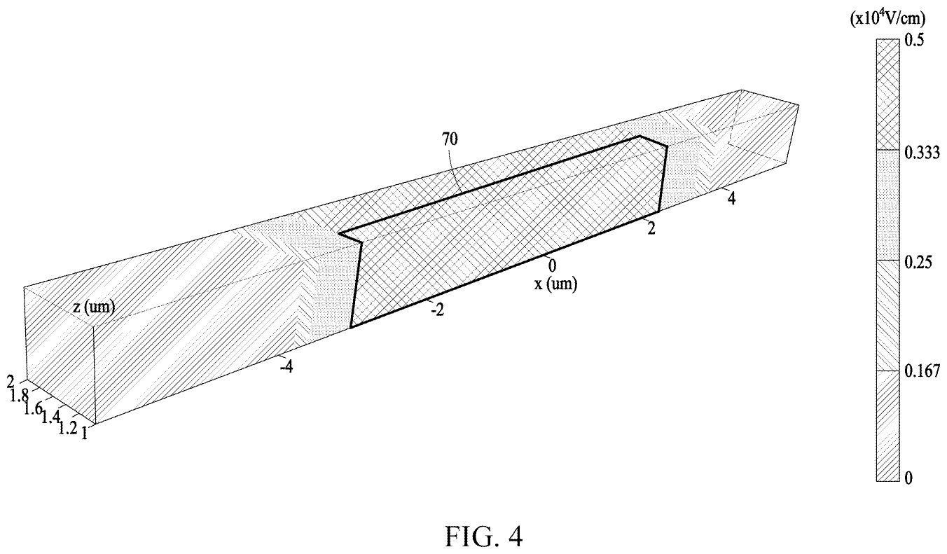

FIG. 4 is a diagram illustrating an example of an electric field intensity distribution in the region 70a with respect to the structure described herein. Referring to FIG. 4, a great part of the region 70 may be affected by a strong electric field of 5 kV/cm or more, and nearly all carriers in the region 70 may be verified to have reached a saturation velocity under the same condition.

Here, a field generated in the region 70 may be construed as the electric field described in FIG. 1A, but expanded three dimensionally, which combines effective points of the vertical PIN structure and the horizontal PIN structure. As a strong electric field can be distributed over a wide region without significantly increasing the traveling distance of the carrier, a traveling time of an entire carrier may be reduced.

The methods described in the example embodiments may be implemented by a program that can be executed on a computer and be implemented in various recording media such as a magnetic storage media, optical storage media, digital storage media, and the like.

Various techniques described herein may be implemented in digital electronic circuitry, computer hardware, firmware, software, or combinations thereof. The techniques may be implemented as a computer program product, i.e., a computer program tangibly embodied in an information carrier, e.g., in a machine-readable storage device (for example, a computer-readable medium) or in a propagated signal, for processing by, or to control an operation of, a data processing apparatus, e.g., a programmable processor, a computer, or multiple computers. A computer program, such as the computer program(s) described above, may be written in any form of a programming language, including compiled or interpreted languages, and may be deployed in any form, including as a stand-alone program or as a module, a component, a subroutine, or other units suitable for use in a computing environment. A computer program may be deployed to be processed on one computer or multiple computers at one site or distributed across multiple sites and interconnected by a communication network.

Processors suitable for processing of a computer program include, by way of example, both general and special purpose microprocessors, and any one or more processors of any kind of digital computer. Generally, a processor will receive instructions and data from a read-only memory or a random-access memory, or both. Elements of a computer may include at least one processor for executing instructions and one or more memory devices for storing instructions and data. Generally, a computer also may include, or be operatively coupled to receive data from or transfer data to, or both, one or more mass storage devices for storing data, e.g., magnetic, magneto-optical disks, or optical disks. Examples of information carriers suitable for embodying computer program instructions and data include semiconductor memory devices, e.g., magnetic media such as hard disks, floppy disks, and magnetic tape, optical media such as compact disk read only memory (CD-ROM) or digital video disks (DVDs), magneto-optical media such as floptical disks, read-only memory (ROM), random-access memory (RAM), flash memory, erasable programmable ROM (EPROM), or electrically erasable programmable ROM (EEPROM). The processor and the memory may be supplemented by, or incorporated in special purpose logic circuitry.

In addition, non-transitory computer-readable media may be any available media that may be accessed by a computer and may include both computer storage media and transmission media.

Although the present specification includes details of a plurality of specific example embodiments, the details should not be construed as limiting any invention or a scope that can be claimed, but rather should be construed as being descriptions of features that may be peculiar to specific example embodiments of specific inventions. Specific features described in the present specification in the context of individual example embodiments may be combined and implemented in a single example embodiment. On the contrary, various features described in the context of a single embodiment may be implemented in a plurality of example embodiments individually or in any appropriate sub-combination. Furthermore, although features may operate in a specific combination and may be initially depicted as being claimed, one or more features of a claimed combination may be excluded from the combination in some cases, and the claimed combination may be changed into a sub-combination or a modification of the sub-combination.

Likewise, although operations are depicted in a specific order in the drawings, it should not be understood that the operations must be performed in the depicted specific order or sequential order or all the shown operations must be performed in order to obtain a preferred result. In a specific case, multitasking and parallel processing may be advantageous. In addition, it should not be understood that the separation of various device components of the aforementioned example embodiments is required for all the example embodiments, and it should be understood that the aforementioned program components and apparatuses may be integrated into a single software product or packaged into multiple software products.

The example embodiments disclosed in the present specification and the drawings are intended merely to present specific examples in order to aid in understanding of the present disclosure, but are not intended to limit the scope of the present disclosure. It will be apparent to those skilled in the art that various modifications based on the technical spirit of the present disclosure, as well as the disclosed example embodiments, can be made.

What is claimed is:

1. A silicon photonics-based photodetector (PD) comprising:
a silicon layer on which doped layers of different types are formed on a surface based on a first spacing based on a center line of an optical waveguide through which an optical signal moves;
a germanium layer being stacked on an upper part of the silicon layer and formed with doped layers of different types on a surface based on a second spacing based on the center line of the optical waveguide; and
a metal electrode configured to generate an electric field by being in contact with the doped layers of the silicon layer and the germanium layer.

2. The silicon photonics-based PD of claim 1, wherein the doped layers formed on the silicon layer and the doped layers formed on the germanium layer are configured to be geometrically asymmetrical based on a horizontal plane of the germanium layer and have opposite doped types.

3. The silicon photonics-based PD of claim 1, wherein the doped layers formed on the silicon layer and the doped layers formed on the germanium layer are configured to be geometrically symmetrical based on a vertical plane of the germanium layer and have opposite doped types.

4. The silicon photonics-based PD of claim 1, wherein a distribution of a fringe electric field formed in the germanium layer is determined by the first spacing between the doped layers formed on the silicon layer and the second spacing between the doped layers formed on the germanium layer.

5. The silicon photonics-based PD of claim 4, wherein, for the distribution of the fringe electric field formed in the germanium layer, a horizontal component of the fringe electric field and a vertical component of the fringe electric field are entirely offset when the first spacing between the doped layers formed on the silicon layer and the second spacing between the doped layers formed on the germanium layer are the same.

6. The silicon photonics-based PD of claim 4, wherein, for the distribution of the fringe electric field formed in the germanium layer, a horizontal component of the fringe electric field is offset, and a vertical component of the fringe electric field is reinforced when the first spacing between the doped layers formed on the silicon layer and the second spacing between the doped layers formed on the germanium layer are different.

7. The silicon photonics-based PD of claim 6, wherein a position where an electric field is reduced by an offset fringe electric field is determined by a difference in the first spacing between the doped layers formed on the silicon layer and the second spacing between the doped layers formed on the germanium layer.

8. The silicon photonics-based PD of claim 1, wherein, of the doped layers of different types formed on the silicon layer, the first spacing is controlled to reduce an amount of loss occurring when a carrier is generated.

9. A silicon photonics-based photodetector (PD) comprising:
a silicon layer on which doped layers of different types are formed on a surface based on a first spacing based on a center line of an optical waveguide through which an optical signal moves; and
a germanium layer on which doped layers being geometrically asymmetrical based on a horizontal plane, geometrically symmetrical based on a vertical plane, and having opposite doped types compared to the doped layers formed on the silicon layer are formed on a surface based on a second spacing.

10. The silicon photonics-based PD of claim 9, wherein a distribution of a fringe electric field formed in the germanium layer is determined by the first spacing between the doped layers formed on the silicon layer and the second spacing between the doped layers formed on the germanium layer.

11. The silicon photonics-based PD of claim 10, wherein, for the distribution of the fringe electric field formed in the germanium layer, a horizontal component of the fringe electric field and a vertical component of the fringe electric field are entirely offset when the first spacing between the doped layers formed on the silicon layer and the second spacing between the doped layers formed on the germanium layer are the same.

12. The silicon photonics-based PD of claim 10, wherein, for the distribution of the fringe electric field formed in the germanium layer, a horizontal component of the fringe electric field is offset, and a vertical component of the fringe electric field is reinforced when the first spacing between the doped layers formed on the silicon layer and the second spacing between the doped layers formed on the germanium layer are different.

13. The silicon photonics-based PD of claim 12, wherein a position where an electric field is reduced by an offset fringe electric field is determined by a difference in the first spacing between the doped layers formed on the silicon layer and the second spacing between the doped layers formed on the germanium layer.

14. The silicon photonics-based PD of claim 9, wherein, of the doped layers of different types formed on the silicon layer, the first spacing is controlled to reduce an amount of loss occurring when a carrier is generated.

15. A silicon photonics-based photodetector (PD) comprising:
a buried oxide (BOX) layer of a silicon-on-insulator (SOI) wafer;
a silicon layer being stacked on an upper part of the BOX layer and formed with doped layers of different types on a surface based on a first spacing based on a center line of an optical waveguide through which an optical signal moves;
a germanium layer being stacked on an upper part of the silicon layer and formed with doped layers of different types on a surface based on a second spacing based on a center line of the optical waveguide; and
a metal electrode configured to generate an electric field by being in contact with the doped layers of the silicon layer and the germanium layer.

16. The silicon photonics-based PD of claim 15, wherein the doped layers formed on the silicon layer and the doped layers formed on the germanium layer are configured to be geometrically asymmetrical based on a horizontal plane of the germanium layer and have opposite doped types.

17. The silicon photonics-based PD of claim 15, wherein the doped layers formed on the silicon layer and the doped layers formed on the germanium layer are configured to be geometrically symmetrical based on a vertical plane of the germanium layer and have opposite doped types.

18. The silicon photonics-based PD of claim 15, wherein a distribution of a fringe electric field formed in the germanium layer is determined by the first spacing between the doped layers formed on the silicon layer and the second spacing between the doped layers formed on the germanium layer.
